(19) United States
(12) Patent Application Publication
(10) Pub. No.: US 2026/0316218 A1
(43) Pub. Date: Oct. 15, 2026

(54) RETAINING RING, CHEMICAL MECHANICAL POLISHING APPARATUS, AND METHOD FOR MANUFACTURING SEMICONDUCTOR DEVICE

(71) Applicant: Renesas Electronics Corporation, Tokyo (JP)

(72) Inventors: Kenichi NOGUCHI, Tokyo (JP); Toshiyasu SUMINAGA, Ibaraki (JP)

(21) Appl. No.: 19/467,406

(22) Filed: Feb. 2, 2026

(30) Foreign Application Priority Data
Mar. 19, 2025 (JP) 2025-045805

(51) Int. Cl. B24B 37/32; B24B 37/20; H10P 52/40; H10P 72/00

(52) U.S. Cl. CPC B24B 37/32; B24B 37/20; H10P 52/407; H10P 72/0428

(57) ABSTRACT

To provide a retaining ring that can improve operational efficiency and reduce manufacturing costs, a chemical mechanical polishing apparatus, and a method for a manufacturing semiconductor device. The retaining ring RTR that holds a wafer includes a first edge, a second edge, a first inner circumference surface, and a second inner circumference surface. The first inner circumference surface is formed in a manner along a central axis from the first edge towards a position between the first edge and the second edge. The second inner circumference surface connects to the first inner circumference surface and is formed to incline away from the central axis towards the second edge from the position. The second inner circumference surface is chamfered to incline against the first inner circumference surface.

### CROSS-REFERENCE TO RELATED APPLICATIONS

The disclosure of Japanese Patent Application No. 2025-045805 filed on Mar. 19, 2025, including the specification, drawings and abstract is incorporated herein by reference in its entirety.

### BACKGROUND

The present invention relates to a retaining ring and a chemical mechanical polishing apparatus, as well as manufacturing method for a semiconductor device, and can be suitably utilized, for example, in polishing processes for insulating films.

The manufacturing process of semiconductor device includes polishing the surface of an interlayer insulating film. The interlayer insulating film is formed to cover a semiconductor substrate on which semiconductor elements are formed. On top of the interlayer insulating film, a wiring layer that is electrically connected to the semiconductor elements is formed. The polishing process is carried out after the interlayer insulating film is formed and before the wiring layer is formed. The chemical mechanical polishing apparatus (CMP apparatus) is used for the polishing process of the interlayer insulating film (Refer Japanese Unexamined Patent Application Publication No. 2010-10351).

The chemical mechanical polishing apparatus includes the retaining ring for holding the semiconductor substrate. During the polishing process, the interlayer insulating film is polished by a polishing pad while the semiconductor substrate is held by the retaining ring. The retaining ring is a consumable item and is periodically replaced with a new retaining ring.

### SUMMARY

When a semiconductor substrate is held by the new retaining ring and the interlayer insulating film is polished, debris (powder) from the retaining ring can be generated due to contact between the semiconductor substrate and the retaining ring. If the debris from the retaining ring gets caught between the interlayer insulating film and the polishing pad during the polishing process, micro-scratches can occur on the surface of the interlayer insulating film.

When micro-scratches form on the surface of the interlayer insulating film, electrical short circuits between different wirings formed on the interlayer insulating film can occur. To avoid this, before polishing the semiconductor substrate of the product with the new retaining ring, measures such as using hundreds of dummy semiconductor substrates for dummy running are adopted. As a result, the operating rate of the chemical mechanical polishing apparatus decreases, becoming a factor that hinders the reduction of production costs.

In light of such circumstances, there is a demand for the retaining ring that can improve the operating rate and reduce manufacturing costs, the chemical mechanical polishing apparatus equipped with such the retaining ring, and furthermore, a manufacturing method for the semiconductor device using such the chemical mechanical polishing apparatus.

Other objects and novel features will become apparent from the description of this specification and the accompanying drawings.

A retaining ring according to one embodiment is applied to a chemical mechanical polishing apparatus and is the retaining ring for holding the polished target. The retaining ring includes a first edge, a second edge, a first inner circumference surface, and a second inner circumference surface. The first edge extends annularly along a direction that intersects a central axis of the retaining ring. The second edge is located opposite the first edge and extends annularly along a direction that intersects the central axis of the retaining ring. The first inner circumference surface is formed along the central axis of the retaining ring from the first edge toward a first position between the first and second edges. The second inner circumference surface connects to the first inner circumference surface and is formed to incline away from the central axis from the first position toward the second edge.

Another embodiment of the chemical mechanical polishing apparatus includes a polishing pad, a polishing head, and a retaining ring. The polishing pad polishes the target subject. The polishing head presses the target subject toward the polishing pad. The retaining ring is attached to the polishing head and holds the target subject. The retaining ring includes a first edge, a second edge, a first inner circumference surface, and a second inner circumference surface. The first edge extends annularly along a direction that intersects a central axis of the retaining ring. The second edge is located opposite the first edge and extends annularly along a direction that intersects the central axis of the retaining ring. The first inner circumference surface is formed along the central axis of the retaining ring from the first edge toward a first position between the first and second edges. The second inner circumference surface connects to the first inner circumference surface and is formed to incline away from the central axis from the first position toward the second edge.

Furthermore, another manufacturing method a semiconductor device includes a process using the aforementioned chemical mechanical polishing apparatus for applying a polishing process to the polished target, and includes the following steps. Preparing the polished target. Forming semiconductor elements on the polished target. Forming an interlayer insulating film on the polished target to cover the semiconductor elements. Applying the polishing process to the interlayer insulating film. Forming a wiring layer on the polished interlayer insulating film. The polishing process includes the following steps. Attaching the retaining ring to the polishing head. Installing the polished target on the retaining ring with the side on which the interlayer insulating film is formed facing the polishing pad. Applying pressure from the polishing head toward the polishing pad while performing the polishing process on the interlayer insulating film on the polished target held by the retaining ring.

According to one embodiment of the retaining ring, it is possible to improve the operating rate and reduce manufacturing costs.

According to another embodiment of the chemical mechanical polishing apparatus, the operating rate of the chemical mechanical polishing apparatus can be improved.

Furthermore, according to another manufacturing method for the semiconductor device, it is possible to reduce manufacturing costs.

### BRIEF DESCRIPTION OF THE DRAWINGS

FIG. 1 is a side view partially in cross-section schematically showing the structure of a chemical mechanical polishing apparatus according to the first embodiment.

FIG. 2 is a plan view of a retaining ring applied to the chemical mechanical polishing apparatus in the same embodiment.

FIG. 3 is a cross-sectional view along the cross-sectional line III-III shown in FIG. 2 in the same embodiment.

FIG. 4 is a partially enlarged cross-sectional view for explaining the shape of the retaining ring in the same embodiment.

FIG. 5 is a cross-sectional view for explaining the shape of the retaining ring in the same embodiment.

FIG. 6 is another partially enlarged cross-sectional view for explaining the shape of the t retaining ring in the same embodiment.

FIG. 7 is a flowchart illustrating the steps of the manufacturing method of a semiconductor device according to the second embodiment.

FIG. 8 is a side view showing the process of step ST1 shown in FIG. 7 in the same embodiment.

FIG. 9 is a side view showing the process of step ST2 shown in FIG. 7 in the same embodiment.

FIG. 10 is a flowchart illustrating the process of chemical mechanical polishing treatment shown in FIG. 7 in the same embodiment.

FIG. 11 is a side view showing each process of steps ST41, ST42, and ST44 shown in FIG. 10 in the same embodiment.

FIG. 12 is a side view showing each process of steps ST42 and ST44 shown in FIG. 10 in the same embodiment.

FIG. 13 is a side view showing the process of step ST43 shown in FIG. 10 in the same embodiment.

FIG. 14 is a partially enlarged cross-sectional view showing the shape of the retaining ring according to a modified example in each embodiment.

### DETAILED DESCRIPTION

### First Embodiment

### Retaining Ring and Chemical Mechanical Polishing Apparatus

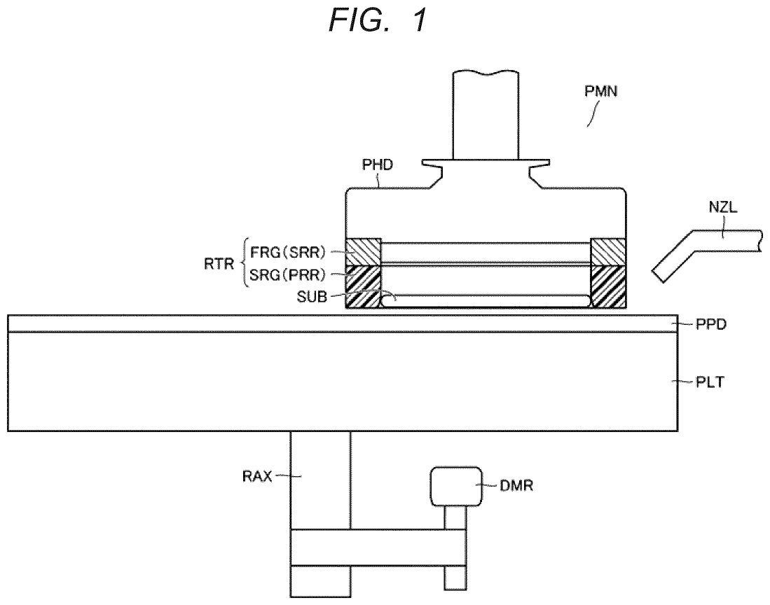

Example according to First Embodiment An exemplary chemical mechanical polishing apparatus according to the first embodiment will be described. As shown in FIG. 1, the chemical mechanical polishing apparatus PMN is equipped with a polishing pad PPD to polish a wafer SUB as an object to be polished, a polishing head PHD to press the wafer SUB toward the polishing pad PPD, a retaining ring RTR to hold the wafer SUB, a platen PLT, a rotating shaft RAX, a motor DMR, and a chemical nozzle NZL.

The polishing pad PPD is pasted on the upper surface of the platen PLT. On the platen PLT, a rotating shaft RAX is installed. By transmitting the driving force of the motor DMR to the rotating shaft RAX, the polishing pad PPD rotates along with the platen PLT. Slurry is supplied to the surface of the rotating polishing pad PPD.

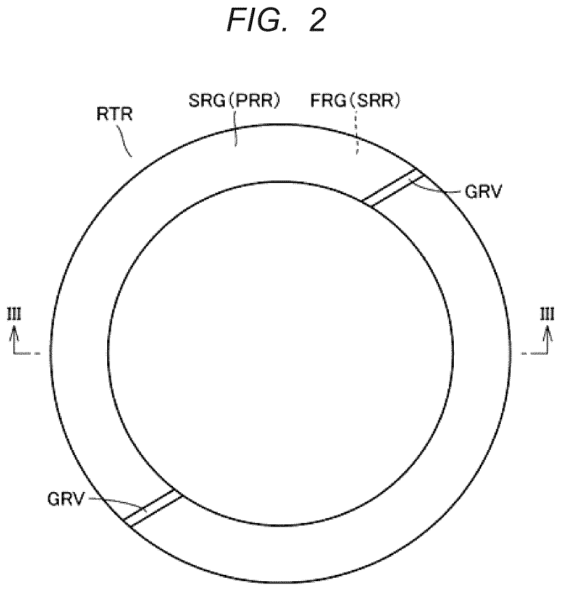

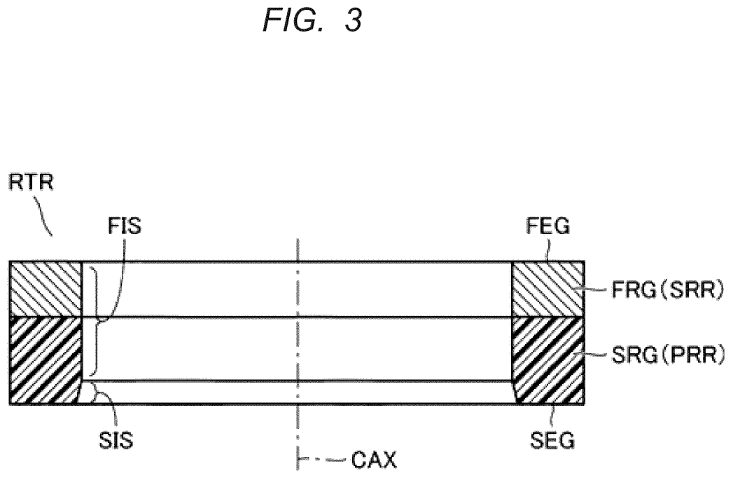

The retaining ring RTR will be described in more detail. Here, an example of an 8-inch wafer SUB will be assumed as the wafer SUB held by the retaining ring RTR. As shown in FIG. 1, the retaining ring RTR is mounted on the polishing head PHD. As shown in FIG. 2 and FIG. 3, the retaining ring RTR to hold the wafer SUB is provided with a first edge FEG, a second edge SEG, a first inner circumference surface FIS, and a second inner circumference surface SIS.

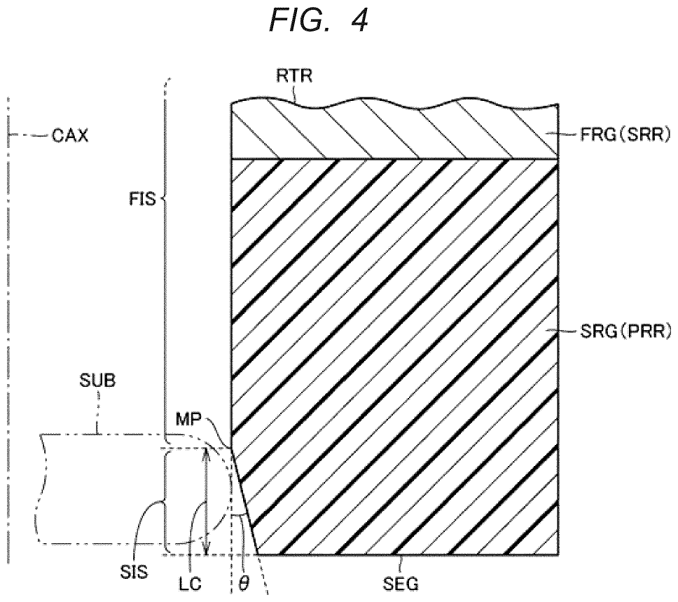

The first edge FEG extends annularly along a direction intersecting a central axis CAX of the retaining ring RTR. The second edge SEG is located opposite the first edge FEG and extends annularly along a direction intersecting the central axis CAX. In other words, the plane including the first edge FEG and the plane including the second edge SEG intersect (approximately perpendicular to) the central axis CAX. The first inner circumference surface FIS is formed from the first edge FEG toward a position MP (first position, see FIG. 4) between the first edge FEG and the second edge SEG along the central axis CAX.

As shown in FIG. 3 and FIG. 4, the second inner circumference surface SIS is connected to the first inner circumference surface FIS and is formed to incline away from the central axis CAX from the position MP to the second edge SEG. Specifically, the second inner circumference surface SIS is chamfered to incline relative to the first inner circumference surface FIS. In FIG. 4, for the convenience of explanation, the state of the central axis CAX being close to the retaining ring RTR is shown.

The retaining ring RTR consists of a first ring FRG and a second ring SRG. The first ring FRG is made of a metal. More specifically, the first ring FRG is made of a stainless steel SRR. The second ring SRG is made of a resin. More specifically, the second ring SRG is made of PPS (Polyphenylene sulfide) resin PRR. The first ring FRG includes part of the first edge FEG and the first inner circumference surface FIS. The second ring SRG includes the second edge SEG, the remaining part of the first inner circumference surface FIS, and the second inner circumference surface SIS.

An inclination angle θ of the second inner circumference surface SIS which is constantly inclined with respect to the first inner circumference surface FIS is, for example, 14 degrees, but it is acceptable as long as it is between 12 degrees and 18 degrees. If the inclination angle θ is less than 12 degrees, scraps of the PPS resin constituting the second ring SRG are likely to occur. On the other hand, if the inclination angle θ exceeds 18 degrees, the polishing rate on the outer circumference side of the wafer SUB becomes relatively fast, and the uniformity of the polishing rate within the wafer SUB surface deteriorates.

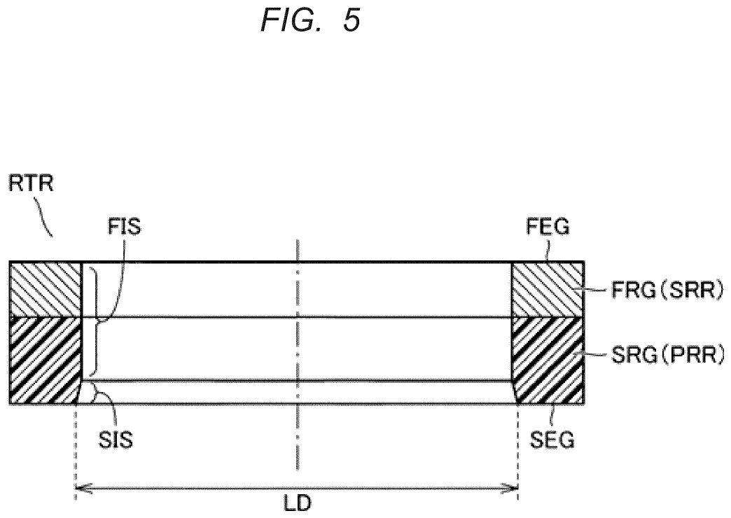

Based on the allowable range of the inclination angle θ, that is 12 degrees or more and 18 degrees or less, a length LC between the position MP along the central axis CAX and the second edge SEG should be between 0.40 mm and 0.50 mm. Additionally, as shown in FIG. 5, a length LD (inner diameter) at the second edge SEG of the second inner circumference surface SIS should be between 200.17 mm and 200.30 mm.

The second inner circumference surface SIS is formed in the second ring SRG using a lathe. At this time, a jig with the inclination angle θ of 14 degrees relative to the first inner circumference surface FIS is used to set the angle of the high-speed bit in advance. In this condition, chamfering is applied to the second ring SRG, allowing for easy formation of the highly accurate second inner circumference surface SIS.

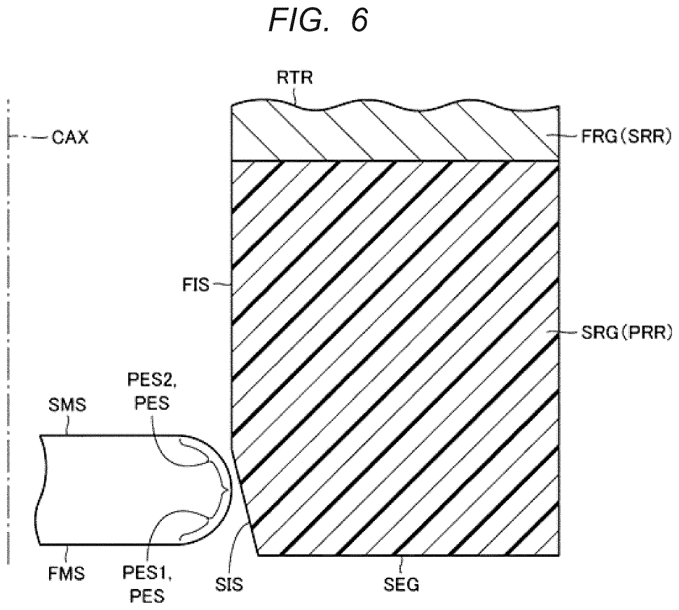

As shown in FIG. 6, the wafer SUB has a first main surface FMS and a second main surface SMS located opposite the first main surface FMS. An interlayer insulating film covering semiconductor elements (not shown) is formed on the first main surface FMS of the wafer SUB. The second main surface SMS is the bottom surface. The wafer SUB is attached to the retaining ring RTR so that the first main surface FMS faces the polishing pad PPD (refer to FIG. 1).

The wafer SUB has an outer circumference surface PES connecting the first main surface FMS and the second main surface SMS. The outer circumference surface PES includes a first outer circumference surface PES1 located near the first main surface FMS and a second outer circumference surface PES2 located near the second main surface SMS.

While the wafer SUB is held in the retaining ring RTR, the first outer circumference surface PES1 does not contact the retaining ring RTR (second ring SRG), and the second outer circumference surface PES2 contacts the retaining ring RTR (second ring SRG).

Additionally, a groove GRV is formed in the second edge SEG of the second ring SRG. As described later, the slurry liquid supplied from the chemical nozzle NZL flows through the groove GRV and is guided directly under the wafer SUB within the retaining ring RTR.

The chemical mechanical polishing apparatus PMN according to the first embodiment and the retaining ring RTR applied to the chemical mechanical polishing apparatus PMN are configured as described above.

### Second Embodiment

### Manufacturing Method of Semiconductor Device

Next, an example of a semiconductor device manufacturing method will be described, including a polishing process to be performed on a wafer SUB using the chemical mechanical polishing apparatus PMN described in the first embodiment.

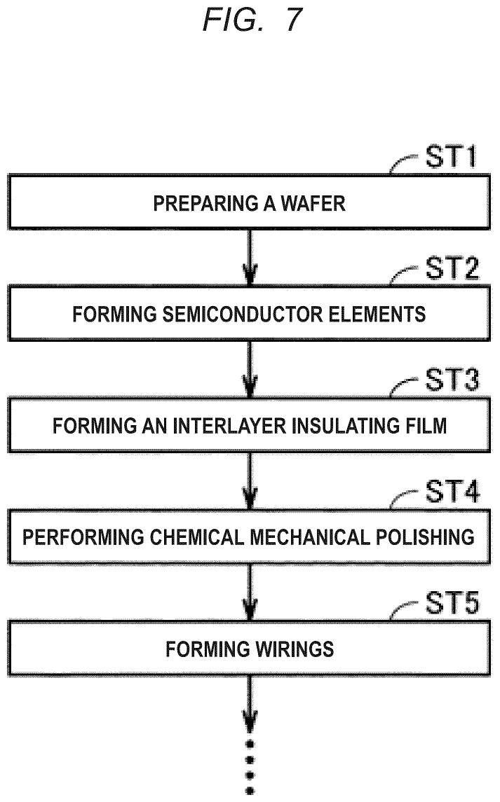

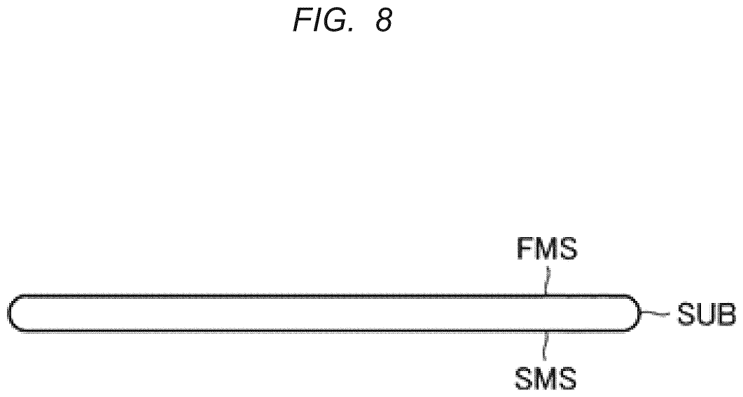

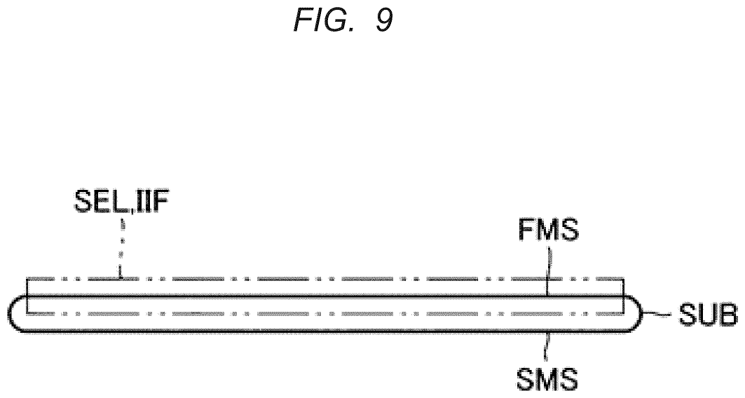

As shown in FIG. 7, first, in step ST1, the wafer SUB (semiconductor substrate) is prepared. As shown in FIG. 8, the wafer SUB has a first main surface FMS and a second main surface SMS. The second main surface SMS is considered the bottom surface. Next, in step ST2, semiconductor elements, etc., are formed. As shown in FIG. 9, the semiconductor elements SEL and the like are formed on the first main surface FMS of the wafer SUB. Next, in step ST3, an interlayer insulating film is formed. As shown in FIG. 9, the interlayer insulating film IIF is formed on the first main surface FMS so as to cover the semiconductor elements SEL, etc.

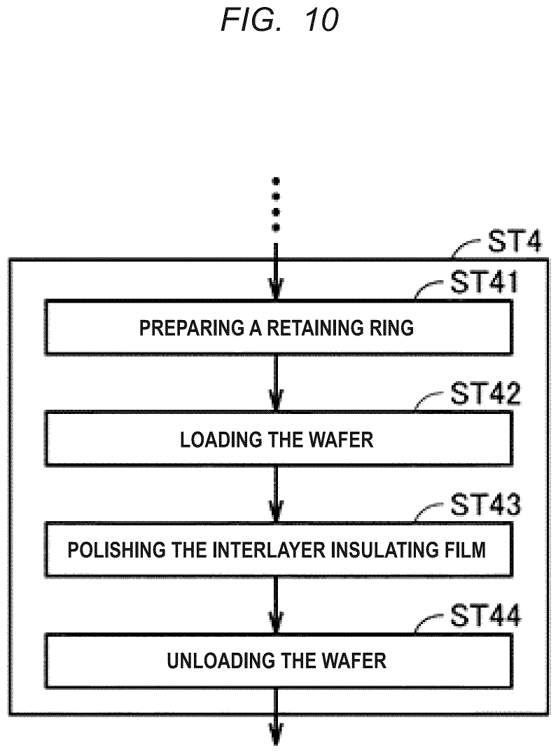

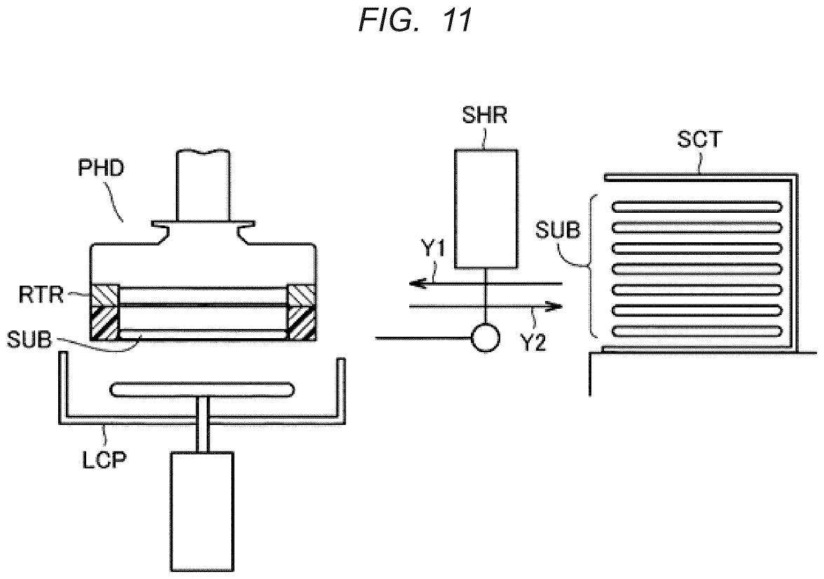

Next, in step ST4, the chemical mechanical polishing process is performed using the chemical mechanical polishing apparatus PMN. Step ST4 will be described in more detail. As shown in FIG. 10, in step ST41, a new retaining ring RTR (see FIG. 2 and FIG. 3) is prepared. The retaining ring RTR is mounted on a polishing head PHD (refer to FIG. 11).

Before polishing the product-targeted wafer using the chemical mechanical polishing apparatus PMN with the newly installed retaining ring RTR, a dummy wafer is inserted and polished beforehand (dummy running).

Next, in step ST42, the product-targeted wafer SUB is introduced into the chemical mechanical polishing apparatus PMN. As shown in FIG. 11, a cassette SCT containing the wafer SUB is placed in a predetermined position for loading and unloading the wafer SUB. A wafer transport robot SHR takes out the wafer SUB housed in the cassette SCT. The taken-out wafer SUB is transported to the load cup LCP as shown by the arrow Y1. The wafer SUB transported to the load cup LCP is held by the retaining ring RTR of the polishing head PHD.

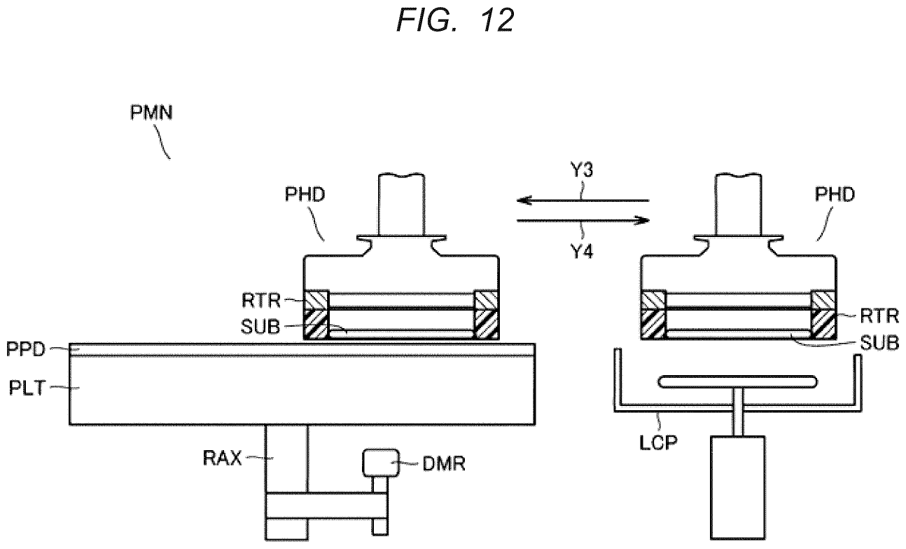

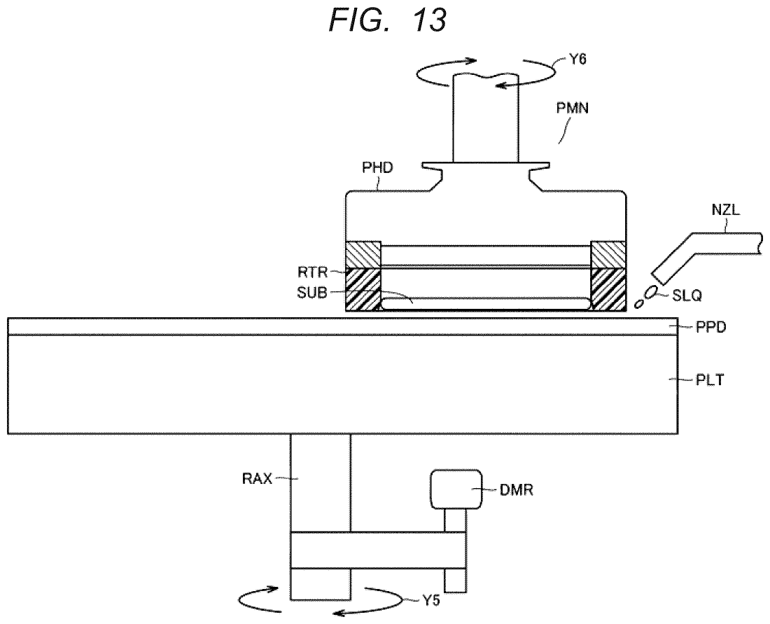

Next, in step ST43, the chemical mechanical polishing process is performed on the wafer SUB. As shown in FIG. 12, the polishing head PHD holding the wafer SUB is positioned to face the polishing pad PPD as shown by the arrow Y3. Next, as shown in FIG. 13, slurry liquid SLQ is supplied toward the polishing pad PPD from the chemical nozzle NZL. Due to the rotary driving force of the motor DMR, the polishing pad PPD rotates along with the platen PLT as shown by the arrow Y5. Meanwhile, the polishing head PHD also rotates as shown by the arrow Y6, and the retaining ring RTR rotates along with the wafer SUB.

By rotating the polishing pad PPD and the retaining ring RTR, the slurry liquid SLQ supplied to the polishing pad PPD flows through the groove GRV formed in the retaining ring RTR (see FIG. 2) and is supplied directly under the wafer SUB. While the slurry liquid SLQ is supplied between the mutually rotating wafer SUB and the polishing pad PPD, the wafer SUB (interlayer insulating film) is polished by the polishing pad PPD.

Next, in step ST44, the wafer SUB, whose polishing process is completed, is removed from the chemical mechanical polishing apparatus PMN and housed in the cassette SCT. As shown in FIG. 12, when the polishing process is completed, the polishing head PHD is transported to the load cup LCP as shown by the arrow Y4, and the wafer SUB held by the retaining ring RTR is taken out. As shown in FIG. 11, the extracted wafer SUB is housed in the cassette SCT by the wafer transport robot SHR. In this way, the chemical mechanical polishing process is completed.

Subsequently, in step ST5 (refer to FIG. 7), wirings and other components are formed on the polished interlayer insulating film, completing the main manufacturing process of the semiconductor device.

In the chemical mechanical polishing apparatus PMN described above, as shown in FIG. 4, the retaining ring RTR holding the wafer SUB has a first inner circumference surface FIS and a second inner circumference surface SIS. The second inner circumference surface SIS has been chamfered from position MP towards a second edge SEG so that it inclines away from a central axis CAX relative to the first inner circumference surface FIS.

The inventors performed polishing on the wafer (interlayer insulating film) using the retaining ring RTR that had undergone chamfering and evaluated the number of scratches that occurred on the wafers. For comparison, the same evaluation was conducted using the retaining ring that had not undergone chamfering.

First, polishing was performed on 25 wafers using the retaining ring that had not undergone chamfering. As a result, the average number of scratches per wafer was 356, compared to the standard average number of 100 or less. Additionally, the maximum number of scratches occurring on a single wafer was 4108, compared to the standard maximum number of 300 or less. Furthermore, the number of wafers with 200 to 300 scratches per wafer amounted to 10.

Next, polishing was performed on 24 wafers using the retaining ring RTR that had undergone chamfering. As a result, the average number of scratches per wafer was 24, compared to the standard average number of less than 100. Furthermore, the maximum number of scratches on a single wafer was 78, compared to the standard maximum number of 300 or less. Additionally, the number of wafers with 200 to 300 scratches per wafer was zero.

From these evaluation results, it was found that applying the retaining ring RTR with chamfering significantly reduces the number of scratches occurring on the surface of the wafer SUB (interlayer insulating film IIF) compared to the retaining ring without chamfering. That is to say, the new retaining ring with chamfering can significantly reduce the debris generated by the retaining ring during the polishing process.

By considerably reducing the debris from the retaining ring, it is possible to substantially lessen the number of wafers required and the processing time required for dummy running, where dummy wafers are inserted into the chemical mechanical polishing apparatus PMN with the attached new retaining ring RTR to perform polishing in advance. As a result, the operating rate of the chemical mechanical polishing apparatus PMN is improved, contributing to the reduction of the semiconductor device manufacturing costs.

Moreover, by significantly reducing the number of micro-scratches on the surface of the interlayer insulating film, it is possible to prevent electrical short circuits between one wiring formed on the interlayer insulating film and other wirings. This contributes to the improvement of a semiconductor device yield and reliability.

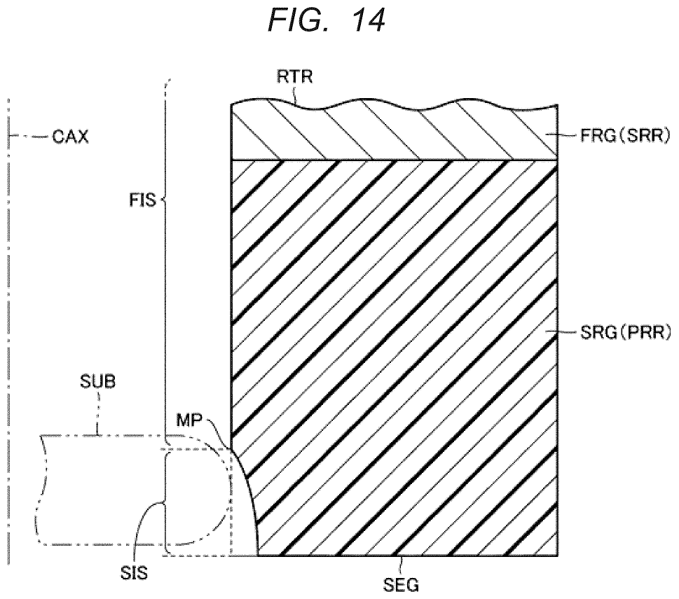

The aforementioned description of the retaining ring RTR used an example where an inclination angle θ of the second inner circumference surface SIS, relative to the first inner circumference surface FIS, was between 12 degrees and 18 degrees. The retaining ring RTR is not limited to the second inner circumference surface SIS with the inclination angle θ relative to the first inner circumference surface FIS. As shown in FIG. 14, the retaining ring RTR may be formed such that the second inner circumference surface SIS gradually moves away from the central axis CAX from the position MP towards the second edge SEG.

The aforementioned chemical mechanical polishing apparatus PMN used an 8-inch wafer SUB as an example. The wafer SUB size is not limited to 8 inches; for example, it may be 12 inches. The 8-inch wafer SUB has a diameter of approximately 200 mm and a thickness of approximately 725 micrometers. On the other hand, a 12-inch wafer SUB has a diameter of approximately 300 mm and a thickness of approximately 775 micrometers.

The thickness difference between the 12-inch wafer SUB and the 8-inch wafer SUB is approximately 50 micrometers. Thus, it is considered that the inclination angle θ of the retaining ring holding the 12-inch wafer SUB is almost unchanged compared to the inclination angle θ (12 degrees to 18 degrees) of the retaining ring holding the 8-inch wafer SUB.

Moreover, a length between the position MP along the central axis CAX and the second edge SEG of the retaining ring holding the 12-inch wafer SUB is also considered to be almost unchanged compared to a length LC (0.40 mm to 0.50 mm) between the position MP along the central axis CAX and the second edge SEG of the retaining ring holding the 8-inch wafer SUB.

Conversely, an inner diameter at the second edge of the second inner circumference surface of the retaining ring holding the 12-inch wafer SUB is ideally regarded as being the size ratio (12/8) times the inner diameter at the second edge of the second inner circumference surface of the retaining ring holding the 8-inch wafer SUB (200.17 mm to 200.30 mm).

The retaining ring and the chemical mechanical polishing apparatus described in the respective embodiments can be variously combined as required.

Although the invention made by the present inventor has been specifically described based on the embodiment, the present invention is not limited to the described embodiment, and it is needless to say that various modifications can be made without departing from the gist thereof.

1. A retaining ring applied to a chemical mechanical polishing apparatus and configured to hold an object to be polished, wherein the retaining ring comprising:
a first edge extending annularly along a direction intersecting a central axis of the retaining ring;
a second edge positioned opposite the first edge and extending annularly along a direction intersecting the central axis of the retaining ring,
a first inner circumference surface formed from the first edge toward a first position between the first edge and the second edge, along the central axis of the retaining ring, and
a second inner circumference surface connected to the first inner circumference surface and formed to incline from the first position toward the second edge in a manner that separates from the central axis.

2. The retaining ring according to claim 1, wherein
the second inner circumference surface is formed to incline at a constant inclination angle with respect to the first inner circumference surface.

3. The retaining ring according to claim 2, wherein
the constant inclination angle is 12 degrees or more and 18 degrees or less.

4. The retaining ring according to claim 1, wherein
an inner diameter at the second edge of the second inner circumference surface is 200.17 mm or more and 200.30 mm or less.

5. The retaining ring according to claim 1, wherein
a length between the first position and the second edge along the central axis is 0.40 mm or more and 0.50 mm or less.

6. The retaining ring according to claim 1, wherein
the second inner circumference surface is formed to gradually separate from the central axis from the first position to the second edge.

7. The retaining ring according to claim 1, further comprising:
a first ring including the first edge, and
a second ring joined to the first ring and including the second edge, wherein
the second ring includes the second inner circumference surface.

8. The retaining ring according to claim 7, wherein
the first ring is made of a metal, and the second ring is made of a resin.

9. The retaining ring according to claim 8, wherein
the metal includes a stainless steel, and the resin includes a PPS resin.

10. A chemical mechanical polishing apparatus comprising:
a polishing pad for polishing an object to be polished,
a polishing head that presses the object to be polished toward the polishing pad,
a retaining ring mounted on the polishing head and configured to hold the object to be polished, wherein the retaining ring comprising:
a first edge extending annularly along a direction intersecting the central axis of the retaining ring;
a second edge positioned opposite the first edge and extending annularly along a direction intersecting the central axis of the retaining ring,
a first inner circumference surface formed from the first edge toward a first position between the first edge and the second edge, along the central axis of the retaining ring, and
a second inner circumference surface connected to the first inner circumference surface and formed to incline from the first position toward the second edge in a manner that separates from the central axis.

11. The chemical mechanical polishing apparatus according to claim 10, wherein
the second inner circumference surface is formed to incline at a constant inclination angle with respect to the first inner circumference surface.

12. The chemical mechanical polishing apparatus according to claim 11, wherein
the constant inclination angle is 12 degrees or more and 18 degrees or less.

13. The chemical mechanical polishing apparatus according to claim 10, wherein the retaining ring comprising:
a first ring is made of a stainless steel and including the first edge; and
a second ring joined to the first ring, is made of the PPS resin, and including the second edge, wherein
the second ring includes the second inner circumference surface.

14. The chemical mechanical polishing apparatus according to claim 10, wherein
the object to be polished is a semiconductor substrate having a first main surface and a second main surface positioned opposite to the first main surface,
the semiconductor substrate includes an outer circumference surface connecting the first and second main surfaces, and
the outer circumference surface comprising:
a first outer circumference surface located on side near the first main surface; and
a second outer circumference surface located on side near the second main surface,
when the semiconductor substrate is held by the retaining ring, the first outer circumference surface does not contact the retaining ring, whereas the second outer circumference surface contacts the retaining ring.

15. A method of manufacturing a semiconductor device including a polishing process performed on the object to be polished using the chemical mechanical polishing apparatus according to claim 10, comprising the steps of:
(a) preparing the object to be polished;
(b) forming semiconductor elements on the object to be polished,
(c) forming an interlayer insulating film on the object to be polished so as to cover the semiconductor elements;
(d) performing the polishing process on the interlayer insulating film; and
(e) forming wirings on the polished interlayer insulating film, wherein
the step of (d) including:
(d1) attaching the retaining ring to the polishing head;
(d2) mounting the object to be polished onto the retaining ring such that a side on which the interlayer insulating film is formed faces the polishing pad; and
(d3) performing the polishing process on the interlayer insulating film while pressing the object to be polished, held by the retaining ring, toward the polishing pad by using of the polishing head.
